(19) United States
(12) Patent Application Publication
(10) Pub. No.: US 2025/0299999 A1
(43) Pub. Date: Sep. 25, 2025

(54) SEALED AXIAL FLUX MOTORS FOR VACUUM ROBOTS

(71) Applicant: Applied Materials, Inc., Santa Clara, CA (US)

(72) Inventors: Damon Keith Cox, Jarrell, TX (US); Whitney Bruce Kroetz, Granger, TX (US); Rajkumar Thanu, Lathrop, CA (US); Pei-Chen Wu, Cupertino, CA (US); Karuppasamy Muthukamatchi, Bangalore (IN); Jeffrey C. Hudgens, San Francisco, CA (US)

(21) Appl. No.: 18/615,617

(22) Filed: Mar. 25, 2024

(51) Int. Cl. H01L 21/687; B25J 18/00; H02K 5/10; H02K 21/24

(52) U.S. Cl. CPC H01L 21/68707; B25J 18/007; H02K 5/10; H02K 21/24

(57) ABSTRACT

A robot includes a robot linkage, and an axial flux motor configured to drive the robot linkage. The axial motor includes a housing, a rotor coupled to the robot linkage, and multiple stator modules within the housing. At least a portion of the housing is to form a sealing barrier between the multiple stator modules and a vacuum environment.

### TECHNICAL FIELD

Embodiments of the present disclosure relate generally to axial flux electric motors, and in particular to sealed axial flux electric motors to power vacuum robots.

### BACKGROUND

An electronic device manufacturing system may include a factory interface (which may be, e.g., an Equipment Front End Module or EFEM) configured to receive substrates upon which electronic devices may be manufactured, a transfer chamber for transferring substrates to and from process chambers, and one or more load locks separating the transfer chamber from the factory interface. The transfer chamber may have a vacuum environment within the chamber and a robot within the transfer chamber may operate within the vacuum environment to transfer substrates. The robot may include seals to isolate components of the robot from the vacuum environment.

### SUMMARY

In an aspect of the disclosure, a robot includes a robot linkage and an axial flux motor configured to drive the robot linkage. The axial flux motor includes a housing, a rotor coupled to the robot linkage, and multiple stator modules within the housing. At least a portion of the housing is to form a sealing barrier between the multiple stator modules and a vacuum environment.

In another aspect of the disclosure, an axial flux motor includes a housing, a rotor configured to couple to a robot linkage, and multiple stator modules within the housing. At least a portion of the housing is to form a sealing barrier between the multiple stator modules and a vacuum environment.

In a further aspect of the disclosure, an axial flux motor includes a housing, a rotor configured to couple to a movable member, a stator coupled to the housing, and one or more rotary seals configured to seal the stator and an inner portion of the rotor from an environment.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

The drawings, described below, are for illustrative purposes only and are not necessarily drawn to scale. The drawings are not intended to limit the scope of the disclosure in any way.

FIG. 1 illustrates a top-down view of an exemplary embodiment of a substrate manufacturing system, including a load lock system, and its placement among other processing chambers and equipment in a factory setting.

FIG. 2A illustrates a perspective view of a robot apparatus, according to some embodiments.

FIG. 2B illustrates a top view of a robot apparatus, according to some embodiments.

FIGS. 3A-3D illustrate side cutaway views of sealed axial flux motors for a vacuum robot, according to some embodiments.

FIGS. 4A-4B illustrate side cutaway views of sealed axial flux motors for a vacuum robot, according to some embodiments.

FIG. 5 illustrates a side cutaway view of a vacuum robot having sealed axial flux motors, according to some embodiments.

FIG. 6A illustrates a schematic diagram of a magnetic bearing for use in a sealed axial flux motor, according to some embodiments.

FIG. 6B illustrates a schematic diagram of a stator for an axial flux motor, according to some embodiments.

FIGS. 7A-7B illustrate side cutaway views of sealed axial flux motors for a vacuum robot, according to some embodiments.

### DETAILED DESCRIPTION OF EMBODIMENTS

Embodiments described herein are related to sealed axial flux motors for vacuum robots. A robot including a sealed axial flux motor as described herein may be used in a processing or manufacturing system, such as a substrate processing or manufacturing system, especially within a vacuum environment of a processing or manufacturing system.

Robots are often used within vacuum environments of processing or manufacturing systems for transporting substrates (e.g., transferring substrates to and/or from process chambers, etc.). Often, robots used in vacuum environments have sealed interiors so that any particles generated by the inner moving parts of the robot (e.g., motor components, drive components such as pulleys and belts, etc.) do not escape into the vacuum environment. Sealing the robots is especially useful in substrate processing or manufacturing where particles that escape the robot into the vacuum environment can adversely affect a substrate should the particles land on the substrate. Errant particles landing on a substrate may result in the substrate being scrapped.

Robots are often powered by electric motors. Conventionally, robots used in vacuum environments (e.g., such as the vacuum environment(s) of a substrate processing or manufacturing system) are powered by radial flux electric motors. Although effective, conventional radial flux electric motors can be large and inefficient. An alternative to the conventional radial flux motor is an axial flux electric motor. An axial flux motor is a type of electric motor where the magnetic flux flows parallel to the motor's shaft, as opposed to a radial flux motor where the magnetic flux flows radially from the center to the periphery of the motor. In axial flux motors, the stator and rotor are arranged in a sandwich-like configuration, with the rotor located between two stator discs or with the stator disc located between two rotors. This design allows for a more compact and efficient motor, as it can achieve higher power density and better cooling compared to traditional radial flux motors.

Axial flux motors are often simpler than conventional radial flux motors, have fewer parts, are smaller with a higher torque density, have increased reliability, provide smoother motion, have lower cogging torque, have higher system stiffness and are often lower cost. However, currently-produced axial flux motors do not lend themselves well to a vacuum environment because they are not sealed and thus may produce particles that escape into the vacuum environment.

Aspects and implementations of the instant disclosure address the above-described and other shortcomings of conventional vacuum robots by providing a vacuum robot having a sealed axial flux motor. In some embodiments, an axial flux motor provides vacuum isolation between a rotor and a stator of the axial flux motor, which allows the user of the high efficiency axial flux motor (as compared to a radial flux motor) in a substrate (e.g., wafer) handling operation. The robot described herein may include a sealed axial flux motor for used in vacuum robotics applications, especially for substrate processing or manufacturing equipment. An axial flux motor described herein may be a universal motor which can be combined or stacked to form multi-axis robot motor drive assemblies. Because the axial flux motors described herein may be stackable, robots with increased number of axes may be easier to design than robots having conventional radial flux electric motors. Additionally, a robot as described herein may be able to take advantage of the numerous benefits of axial flux motors as described herein.

In some embodiments, a robot includes a robot linkage. The robot linkage may include a substrate-handling end effector on the end of the linkage. In some embodiments, the robot linkage is coupled with another linkage with an articulating joint between the two linkages. In some embodiments, the robot includes an axial flux motor that is to drive the robot linkage. The robot linkage may be driven directly by a component of the axial flux motor or indirectly such as through a belt-and-pulley drive system, etc. In some embodiments, the axial flux motor includes a housing to house the various components of the motor. For example, the housing may house the mechanical components of the motor such as the rotor, the stator (e.g., the components that make up the stator, etc.), bearing(s), shaft(s), wiring components, cooling components, etc. In some embodiments, the housing is sealed with various sealing components such as o-ring(s), lip seal(s), etc. Sealing the housing may reduce the number of particles that may escape the motor into a vacuum environment. In some embodiments, a rotor of the axial flux motor is coupled to the robot linkage. As described herein, the rotor may be directly coupled to the robot linkage or may be indirectly coupled.

In some embodiments, the axial flux motor includes multiple individual stator modules that make up the stator. In some embodiments, the axial flux motor is a brushless motor. Each of the individual stator modules may be individually controlled. Each of the stator modules may include multiple conductive windings wound around a core. The stator modules may interact with permanent magnets of the rotor (e.g., interact by electro-magnetic force, etc.) to cause the rotor (e.g., and thus the robot linkage) to rotate. Each one of the stator modules may be housed within individual pockets formed in the housing. In some embodiments, at least part of the housing forming the pockets is to form a sealing barrier between the multiple stator modules and a vacuum environment. Because the stator modules include multiple conductive windings (e.g., multiple copper windings, etc.) that are subject to corrosion and/or deterioration over time, the stator modules should be sealed from the vacuum environment so that particles from the corrosion and/or deterioration are not introduced into the vacuum environment. The rotor may include permanent magnets which are not subject to corrosion and/or deterioration over time, so the rotor can be safely exposed to the vacuum environment without the risk of particle production.

Embodiments of the present disclosure provide advantages over conventional systems described above. Particularly, some embodiments described herein provide a vacuum robot having an axial flux motor that is sealed to reduce the amount of particles that can escape the motor into the vacuum environment. The axial flux motor may have several advantages over conventional radial flux motors such as less friction, lower inertia, higher stiffness, greater torque density, smoother motion, faster setting time, greater accuracy, higher throughput, improved serviceability, improved reliability, and/or lower cost. Additionally, the seals of an axial flux motor as described herein may reduce the amount of particles introduced into the vacuum environment which may reduce the number of scrapped substrates in a substrate manufacturing or processing system, leading to overall greater system throughput.

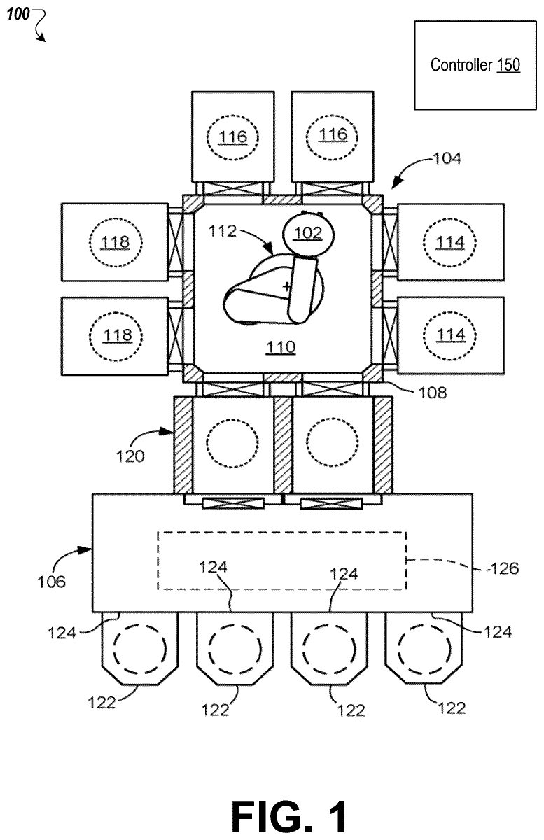

Referring now to the figures, FIG. 1 is a diagram of a cluster tool 100 (also referred to as a system, substrate processing system or manufacturing system) that is configured for substrate fabrication (e.g., for fabrication of semiconductor devices, displays, photovoltaic devices, etc.) in accordance with at least some embodiments of the disclosure. In some embodiments, manufacturing cluster tool 100 may include a processing portion 104, a transfer chamber 110, a load lock 120, a factory interface 106, and substrate carriers 122 or front opening unified pods (FOUPs). Processing portion 104 may include multiple process chambers 114, 116, and 118, wherein specific and controlled substrate manufacturing processes occur. Transfer chamber 110 may house a transfer robot 112 including a substrate transfer mechanism, or end effector (substrate transfer mechanism and end effector will be used interchangeable moving forward in the disclosure) that may transport substrates 102. The transfer robot 112 may include scaled axial flux motors as described herein. Transfer chamber 110 may be in transfer chamber housing 108. Load lock 120 may interface with both the processing portion 104 and the factory interface 106. Factory interface 106 may include a factory interface robot 126, for transferring substrates to and from the carriers 122 and the load lock 120. The factory interface robot 126 may include sealed axial flux motors as described herein. Factory interface may further comprise a plurality of load ports 124 for receiving carriers 122 carrying one or more substrates. Transfer chamber 110 is generally maintained at vacuum pressure levels, while factory interface 106 is generally maintained at atmospheric pressure.

In some embodiments, transfer chamber 110 and process chambers 114, 116, and 118, may be maintained at a vacuum level. Load lock 120 may alternate pressures between a vacuum level (e.g., when opened to transfer chamber 110) and atmospheric pressure (e.g., when opened to factory interface 106). The vacuum level for the transfer chamber 110 may range from about, e.g., 0.01 Torr (10 mTorr) to about 80 Torr. Other vacuum levels may be used.

The factory interface robot 126 may be configured to transfer the substrate from the substrate carriers 122 to load locks 120 through load lock doors. The number of load locks can be more or less than two but for illustration purposes only, two load locks 120 are shown with each load lock having a door (e.g., a slit valve) to connect it to the factory interface 106 and a door to connect it to the transfer chamber 110. Load locks 120 may or may not be batch load locks. In embodiments, the load locks are smart load locks capable of performing self-diagnosis and/or automated prevention and/or recovery. In embodiments, the load locks include one or more substrate support devices having integrated sensors that provide “smart” functionality for the load locks. The substrate support devices used in embodiments are described in further detail below.

The load locks 120, under the control of a controller 150, can be maintained at either an atmospheric pressure environment or a vacuum pressure environment, and serve as an intermediary or temporary holding space for a substrate that is being transferred to/from the transfer chamber 110. The transfer chamber includes transfer robot 112 that is configured to transfer the substrate from the load locks 120 to one or more of the multiple processing chambers 114, 116, 118 (also referred to as process chambers), or to one or more pass-through chambers (also referred to as vias), without vacuum break, i.e., while maintaining a vacuum pressure environment within the transfer chamber 110 and the multiple processing chambers 114, 116, 118. The load locks 120 may be used to hold hot substrates that are at an elevated temperature due to recent processes performed on the substrates. In some embodiments, the substrate support device in the load lock includes a temperature sensor to measure the temperature of the substrate. The substrate may be held until the substrate cools down to a target temperature, after which the factory interface robot may retrieve the substrate from the load lock 120. Additionally, the load locks 120 may be used to hold substrates while they are heated to pre-processing temperatures that are close to temperatures that the substrates will be heated to during processing by one or more processing chambers 114, 116, 118. The load locks 120 may include one or more heaters disposed therein for heating of the substrates. In some embodiments, the substrate support device in the load lock includes a temperature sensor to measure the temperature of the substrate. The substrate may be held until the substrate is heated to a target temperature, after which the transfer chamber robot may retrieve the substrate from the load lock 120.

A door, e.g., a slit valve door, connects each respective load lock 120 to the transfer chamber 110. A door also connects each respective load lock 120 to the factory interface 106. The multiple processing chambers 114, 116, 118 are configured to perform one or more processes. Examples of processes that may be performed by one or more of the processing chambers 114, 116, 118 include cleaning processes (e.g., a pre-clean process that removes a surface oxide from a substrate), anneal processes, deposition processes (e.g., for deposition of a cap layer, a hard mask layer, a barrier layer, a bit line metal layer, a barrier metal layer, etc.), etch processes, and so on. Examples of deposition processes that may be performed by one or more of the process chambers include physical vapor deposition (PVD), chemical vapor deposition (CVD), atomic layer deposition (ALD), and so on. Examples of etch processes that may be performed by one or more of the process chambers include plasma etch processes.

Controller 150 (e.g., a tool and equipment controller, a tool cluster controller, etc.) may control various aspects of the cluster tool 100, e.g., gas pressure in the processing chambers, individual gas flows, spatial flow ratios, plasma power in various process chambers, temperature of various chamber components, radio frequency (RF) or electrical state of the processing chambers, and so on. The controller 150 may receive signals from and send commands to any of the components of the cluster tool 100, such as the robot arms 112, 126, process chambers 114, 116, 118, load locks 120, substrate supports of load locks, slit valve doors, and/or one or more sensors (e.g., integrated in one or more substrate supports of load locks), and/or other processing components of the cluster tool 100. The controller 150 may thus control the initiation and cessation of processing, may adjust a deposition rate and/or target layer thickness, may adjust process temperatures, may adjust a type or mix of deposition composition, may adjust an etch rate, may initiate automated prevention and/or recovery processes on the load lock 120, and the like. The controller 150 may further receive and process sensor measurement data (e.g., optical measurement data, vibration data, spectrographic data, particle detection data, temperature data, etc.) from various sensors (e.g., sensors integrated into substrate support devices of load locks 120) and make decisions based on such measurement data.

In various embodiments, the controller 150 may be and/or include a computing device such as a personal computer, a server computer, a programmable logic controller (PLC), a microcontroller, and so on. The controller 150 may include (or be) one or more processing devices, which may be general-purpose processing devices such as a microprocessor, central processing unit, or the like. More particularly, the processing device may be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device may also be one or more special-purpose processing devices such as an application specific integrated circuit (ASIC), a field programmable gate array (FPGA), a digital signal processor (DSP), network processor, or the like. The controller 150 may include a data storage device (e.g., one or more disk drives and/or solid state drives), a main memory, a static memory, a network interface, and/or other components. The processing device of the controller 150 may execute instructions to perform any one or more of the methodologies and/or embodiments described herein. The instructions may be stored on a computer readable storage medium, which may include the main memory, static memory, secondary storage and/or processing device (during execution of the instructions). In some embodiments, controller 150 is a dedicated controller for load lock(s) 120.

In embodiments, the processing device and memory of controller 150 have an increased capacity as compared to processing power and memory size of traditional controllers for cluster tools. In embodiments, the processing device and memory are sufficient to handle parallel execution and use of multiple trained machine learning models, as well as training of the machine learning models. For example, the memory and processing device may be sufficient to handle parallel execution of 6-15 different machine learning models (e.g., one or more for each of the process chambers 114, 116, 118, and/or load locks 120).

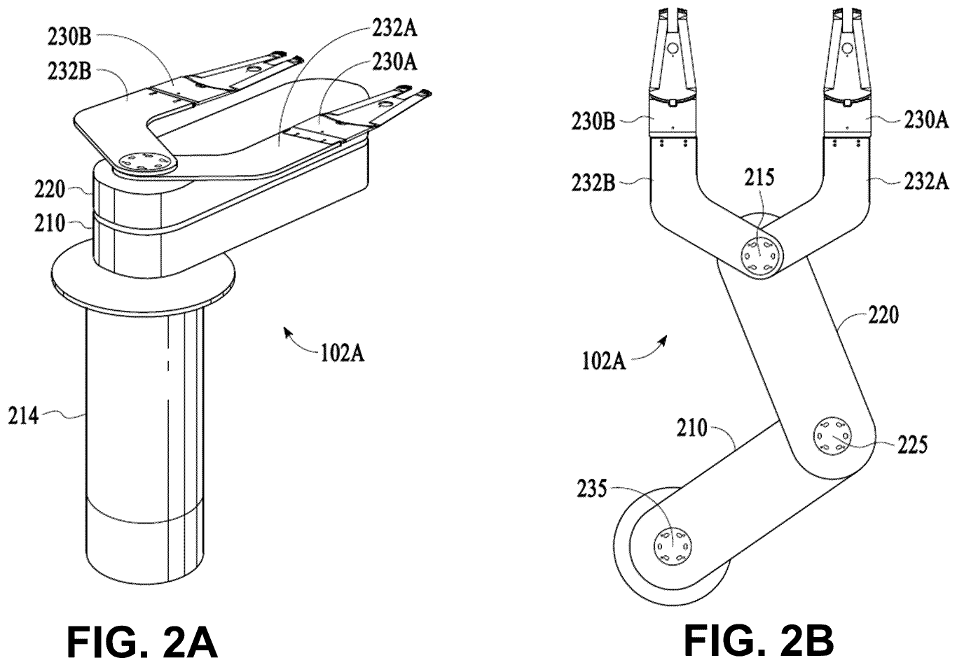

FIG. 2A illustrates a perspective view of a robot apparatus 212 according to some embodiments. FIG. 2B illustrates a top view of robot apparatus 212 according to some embodiments. In some embodiments, robot apparatus 212 is illustrated having dual end effectors. However, in some embodiments, a robot apparatus can have a single end effector or any number of end effectors. The robot apparatus 212 may include one lower arm 210 configured to rotate about the first rotational axis 215. For example, one or more motors (not shown) located in the base 214 may rotate the one lower arm 210 about the first rotational axis 215. The one or more motors may be sealed axial flux motors as described herein. The robot apparatus 212 may further include one upper arm 220 rotatably coupled to the one lower arm 210 at a second rotational axis 225 that is spaced away from the first rotational axis 215. Upper arm 220 may be configured to rotate about the second rotational axis 225. For example, one or more motors (not shown) located in the base 214 may rotate the one upper arm 220 about the second rotational axis 225. In some embodiments, portions of the lower arm 210 and portions of the upper arm 220 may operate on different planes, one above the other.

The robot apparatus 212 may further include a first end effector 230A that is rotatably coupled to the one upper arm 220 at a third rotational axis 235 spaced from the second rotational axis 225. The first end effector may include a first bend 232A in a first direction within a horizontal plane. The robot apparatus 102A may also include a second end effector 230B that is rotatably coupled to the one upper arm 220 at the third rotational axis 235. The second end effector may include a second bend 232B in a second direction within a horizontal plane, wherein the second direction is opposite the first direction. The first end effector 230A and the second end effector 230B may be configured to rotate independently about the third rotational axis 235 for both, the dual substrate handling mode and the single substrate handling mode. For example, one or more motors (not shown) located in the base 214 may independently rotate the first end effector 230A and second end effector 230B about the third rotational axis 235 or both, the dual substrate handling mode and the single substrate handling mode. In some embodiments, the first end effector 230A and/or the second end effector 230B are sufficiently thin to fit between a wafer slot (e.g., of a substrate carrier) to retrieve or place a substrate (e.g., in a substrate carrier).

In some embodiments, vibration from movement of the lower arm 210 and/or the upper arm 220 may be propagated through the first end effector 230A and/or the second end effector 230B. In some embodiments, the first end effector 230A and the second end effector 230B include embedded CNTs to dampen vibration in the end effector. In some embodiments, the first end effector 230A and/or the second end effector 230B are made of a matrix material having embedded CNTs. For example, the first end effector 230A and/or the second end effector 230B may be made of a metal, a ceramic, or a polymer matrix embedded with CNTs. In some embodiments, the first end effector 230A and/or the second end effector 230B are formed out of an aluminum matrix with embedded CNTs. The embedded CNTs within the matrix material may dampen vibration within the first end effector 230A and/or the second end effector 230B so that vibration settles below a threshold amplitude within a threshold amount of time. In some embodiments, because CNTs are electrically conductive, the first end effector 230A and/or the second end effector 230B may be at least partially electrically conductive.

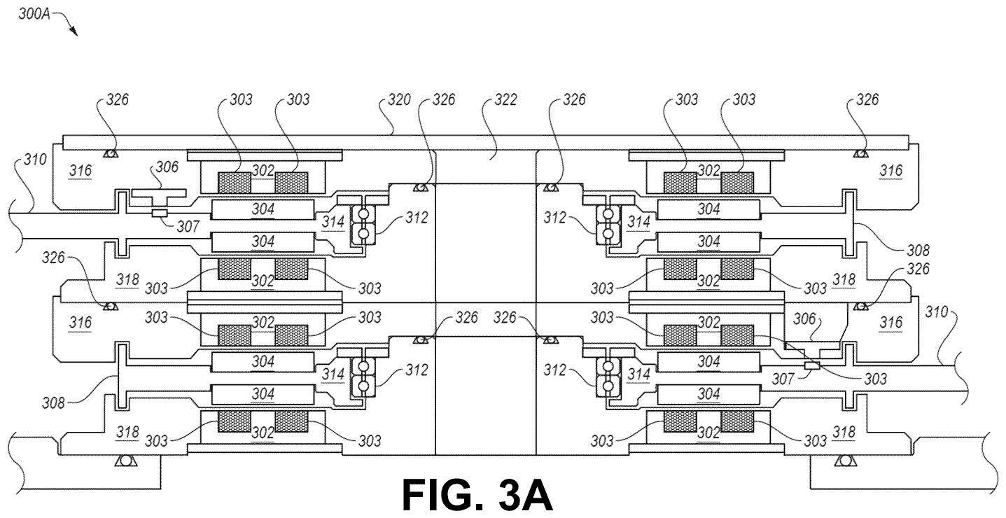

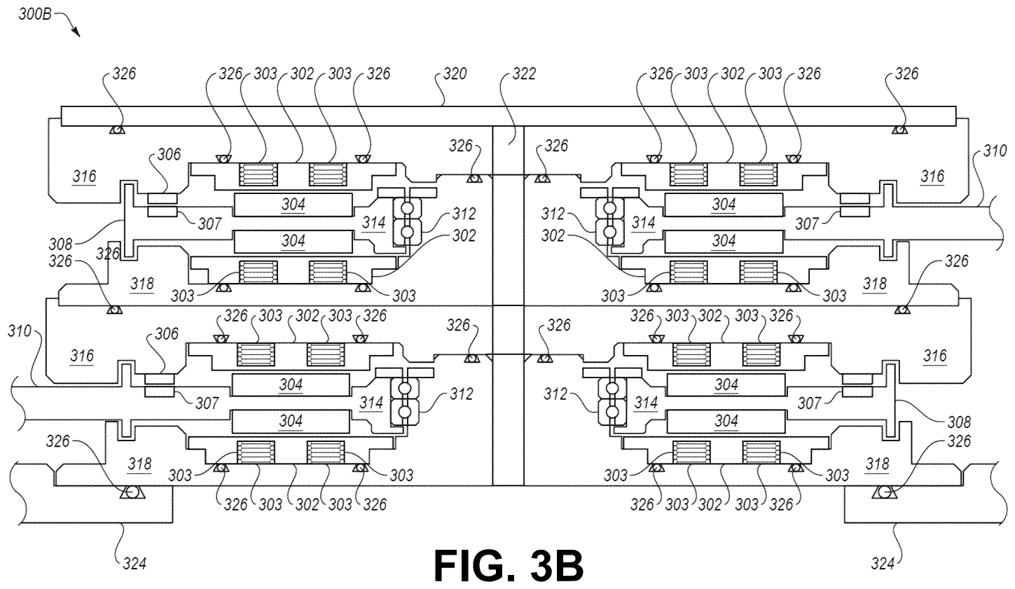

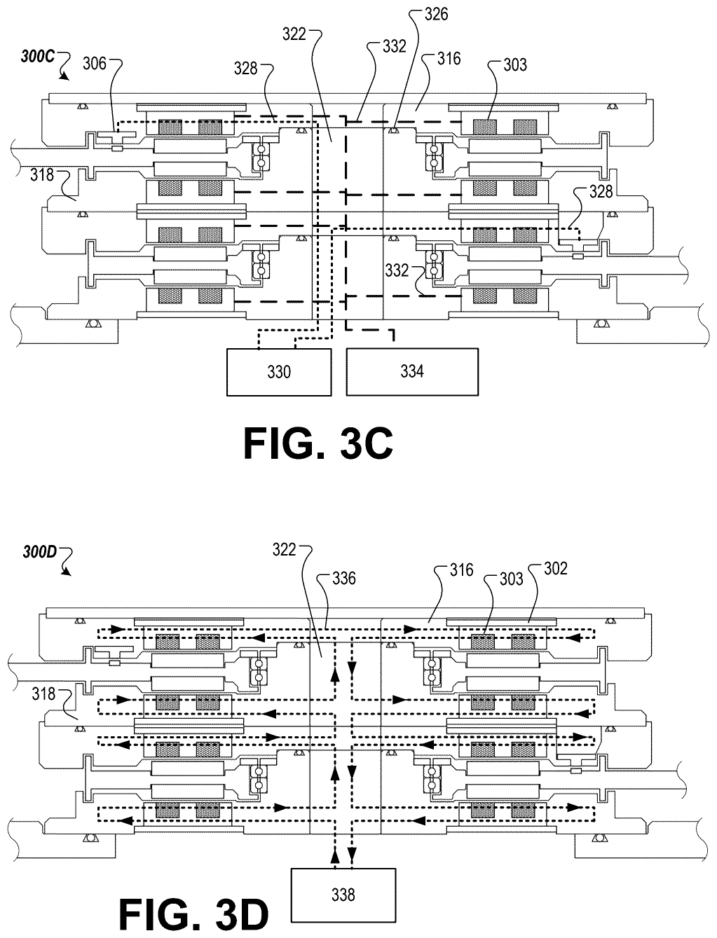

FIG. 3A illustrates a side cutaway view 300A of a sealed axial flux motor for a vacuum robot, according to some embodiments. View 300A may show two such sealed axial flux motors, one stacked on top of the other. In some embodiments, a first axial flux motor is disposed adjacent to a second axial flux motor (e.g., one stacked on top of the other). In some embodiments, the second axial flux motor shares a common axis with the first axial flux motor. In some embodiments, the axial flux motors shown in view 300A are central rotor-type axial flux motors. In some embodiments, an axial flux motor includes one or more seals and/or barriers to isolate at least a portion of the motor from a vacuum environment. Particularly, components that are susceptible to corrosion and/or deterioration may be sealed from the vacuum environment because such components may generate particles which are harmful to substrates in the vacuum environment.

In some embodiments, an axial flux motor includes multiple stator modules 302. Together, the multiple stator modules 302 may make up a stator of the motor. Each of the stator modules 302 may include windings 303 which may include conductive windings (e.g., copper windings, etc.) wound around a core. The stator modules may be disposed within pockets formed in components making up a housing. In some embodiments, a first housing 316 and a second housing 318 together form a housing to house the motor components. In some embodiments, the first housing 316 is a top housing and the second housing 318 is a bottom housing. The relative terms “top” and “bottom” are used herein for convenience but are not limiting. It should be understood that in some instances, the top component (e.g., first housing 316, etc.) may be disposed above the bottom component (e.g., second housing 318). The first housing 316 may form an upper portion of the housing and the second housing 318 may form a lower portion of the housing. The region between the first housing 316 and the second housing 318 may be sealed by one or more seals (e.g., o-ring seals as described herein). The first housing 316 may form multiple pockets to house multiple stator modules 302 on a top side of the rotor 314 and the second housing 318 may similarly form multiple pockets to house multiple stator modules 302 and a bottom side of the rotor 314. In some embodiments, the stator modules 302 are arranged radially about a hollow center channel 322 that forms a central axis of the axial flux motor. In some embodiments, the stator modules 302 form “pie”-shaped modules arranged radially around a central axis of the housing. In some embodiments, the stator modules 302 are disposed in either side of the rotor 314. For example, a first set of stator modules 302 are disposed on a first side (e.g., a top side) of rotor 314 and a second set of stator modules 302 are disposed on a second side (e.g., a bottom side) of rotor 314 opposite the first side.

In some embodiments, the stator modules 302 are replaceable. As shown in view 300A, the stator modules are replaceable from a back side (e.g., an outer side) of either the first housing 316 or the second housing 318. For example, the stator modules 302 housed in pockets of first housing 316 may be replaceable via the top of first housing 316 while the stator modules 302 housed in pockets of the bottom housing 316 may be replaceable via the bottom of second housing 318. In some embodiments, the inner portion of the pockets (e.g., the bottom of the pockets in first housing 316 and the top of the pockets in second housing 318) forms a scaling barrier between the stator modules 302 and the vacuum environment in which the motor is to operate. The sealing barrier, together with the seals formed by o-rings 326 (e.g., described herein below), may seal the windings 303 from the vacuum environment.

In some embodiments, the rotor includes multiple magnets 304 to interact with the stator modules 302. When the windings 303 are excited by electrical current, an electro-magnetic field may be produced which may cause electro-magnetic forces that drive the magnets 304. The rotor 314 may thus be caused to rotate. In some embodiments, the rotor 314 may be coupled to a movable member such as a robot linkage (e.g., a robot arm, etc.), a rotary table, and/or a chuck. A robot arm 310 may be coupled to the rotor 314 and may transfer a substrate when the rotor 314 rotates. An encoder head 306 may monitor multiple encoder windows 307 arranged radially around the rotor 314 so that a controller receiving sensor data from the encoder head 306 may determine the rotational magnitude and/or rotational velocity of the rotor 314. The encoder 306 may utilize optics to monitor the passage of encoder windows 307 as the rotor 314 rotates. For example, the encoder windows 307 may be made of a transparent (e.g., substantially transparent) material. When an encoder window 307 passes by the encoder head 306 (e.g., when the non-transparent material between encoder windows 307 passes by the encoder head 306), the encoder head 306 may generate a signal indicative of the rotation of the rotor 314.

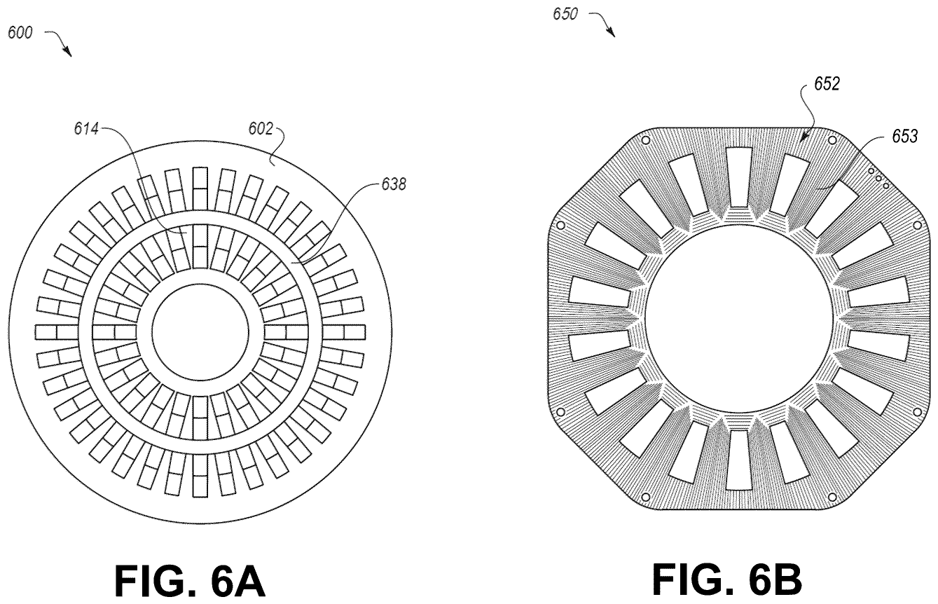

In some embodiments, bearings 312 support the rotor 314. The bearings 312 may provide a rotational coupling between the rotor 314 and the lower housing 318. In some embodiments, the bearings 312 are roller bearings such as ball bearings, etc. In some embodiments, the bearings 312 are one or more magnetic bearings such as those described herein below with respect to FIG. 6A. An inner race of the bearings 312 may be positioned on a hub of the lower housing 318 while an outer race of the bearings 312 may be coupled to the rotor 314. The bearings 312 may be positioned substantially within a center portion formed by the rotor 314 and the rotor 314 may rotate outboard of the bearings 312. In some embodiments, the rotor 314 includes an outer guard 308 to eliminate pinch points between the first housing 316 and the second housing 318. The guard 308 may protrude into corresponding channels formed in the first housing 316 and the second housing 318.

In some embodiments, two or more motors can be stacked one on top of the other as shown in view 300A. For example, a second housing 318 of a first motor can be coupled on top of a first housing 316 of a second motor. A cap 320 can be coupled on top of the first housing 316 of the first motor. In some embodiments, the second housing 318 (e.g., of the second motor) can be coupled to a base 324. One or more seals may be disposed between the first housing 316, the second housing 318, the base 324, and/or the cap 320. The seals may be provided by o-rings 326 disposed within grooves formed in the first housing 316, the second housing 318, and/or the base 324. For example, a first o-ring 326 may be disposed within a groove formed in a first face (e.g., a top face) of first housing 316 near an outer periphery of the first housing 316. The first o-ring 326 may form a seal between the first housing 316 and a second housing 318 (e.g., of another motor) or between the first housing 316 and a cap 320. A second o-ring 326 may be disposed within a groove formed in a second face of the second housing 318 near a hub of the second housing 318. The second o-ring 326 may form a seal between the second housing 318 and the first housing 316. A third o-ring 326 may be disposed within a groove formed in the base 324. The third o-ring 326 may form a seal between the base 324 and the bottom housing 316. The seals formed by the o-rings 326 may at least partially seal the motor components from the vacuum environment in which the motor is to operate.

FIG. 3B illustrates a side cutaway view 300B of a sealed axial flux motor for a vacuum robot, according to some embodiments. View 300B may show two such sealed axial flux motors, one stacked on top of the other. In some embodiments, the axial flux motor(s) shown in view 300B have many substantially same features as shown in view 300A. In some embodiments, the features in view 300B having the same numbering as those in view 300A have the same structure and/or function.

In some embodiments, as shown in view 300B, the stator modules 302 are replaceable via a front side (e.g., an inner side) of the first housing 316 and the second housing 318. In some embodiments, the stator modules 302 are coupled to the first housing 316 or the second housing 318 and sealed with a fourth o-ring 326. The fourth o-ring 326 may form a seal between a corresponding stator module 302 and the corresponding portion of the housing (e.g., either the first housing 316 or the second housing 318). In some embodiments, a body of an individual stator module 302 forms a sealing barrier between the windings 303 and the vacuum environment.

FIG. 3C illustrates a side cutaway view 300C of a sealed axial flux motor for a vacuum robot, according to some embodiments. View 300C shows the arrangement of wiring to power and control the axial flux motor. In some embodiments, an electrical signal from encoder head 306 is sent through an encoder wire 328 to an encoder module 330. The encoder module 330 may be a module of a controller to control the axial flux motor. The encoder wire 328 may be routed through the center channel 322 and into the first housing 316. In some embodiments, electrical signals are sent via motor wires 332 to the windings 303 from the phase and current module 334. The phase and current module 334 may be a module of a controller to control the axial flux motor. The motor wires may be routed through the center channel 322 and into the first housing 316 and the second housing 318. In some embodiments, the center channel 322 is sealed from the vacuum environment (e.g., by one or more seals formed by the o-rings 326).

FIG. 3D illustrates a side cutaway view 300D of a sealed axial flux motor for a vacuum robot, according to some embodiments. In some embodiments, the axial flux motor is cooled by liquid cooling. Liquid cooling lines 336 may be routed through the first housing 316 and/or the second housing 318 to cool the windings 303 in the stator modules 302. In some embodiments, a cooling module 338 provides cooled liquid to cool the motor. Heat may be carried away from the motor through the cooling lines 336 back to the cooling module 338. In some embodiments, the cooling lines 336 are routed through the center channel 322. In some embodiments, the center channel 322 is sealed from the vacuum environment.

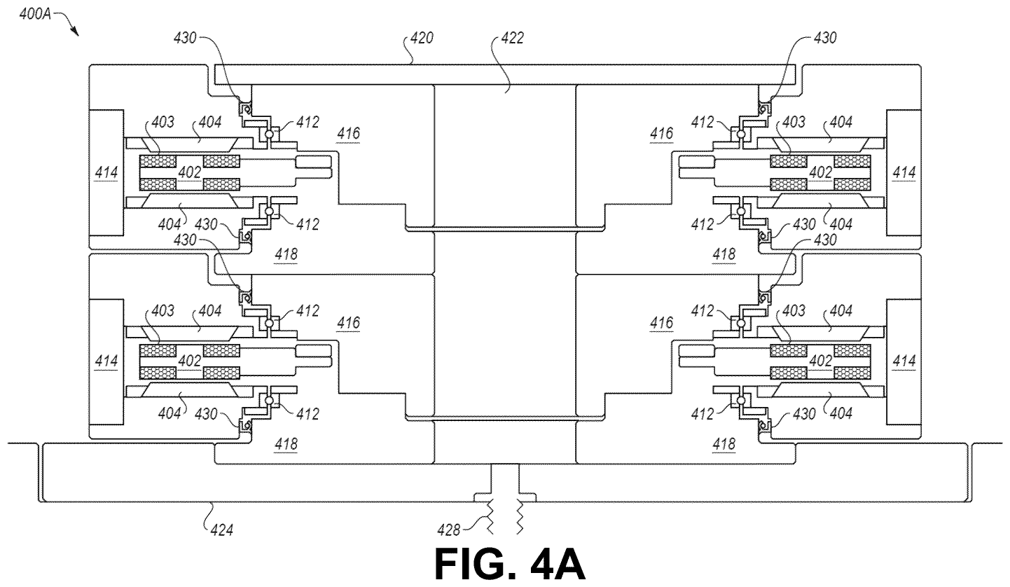

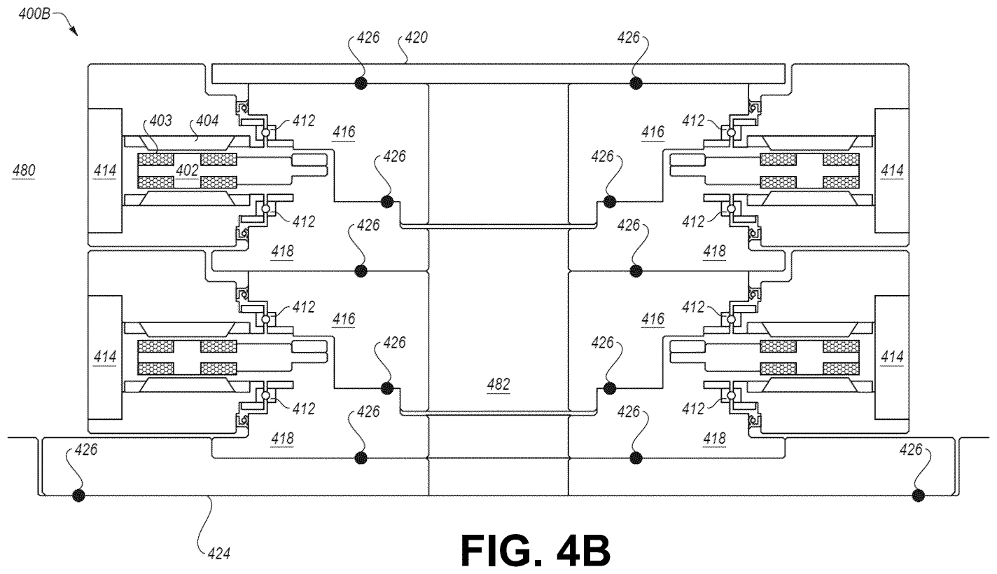

FIG. 4A illustrates a side cutaway view 400A of a sealed axial flux motor for a vacuum robot, according to some embodiments. View 400A may show two such sealed axial flux motors, one stacked on top of the other. In some embodiments, the axial flux motors shown in view 400A are central stator-type axial flux motors. In some embodiments, features shown in view 400A having similar numbering to those shown in one of views 300A-300B may have similar features and/or functionality. For example, shown in view 400A are stator modules 402, windings 403, magnets 404, bearings 412, rotor 414, first housing 416 (e.g., a top housing), second housing 418 (e.g., a bottom housing), cap 420, center channel 422, and base 424. In some embodiments, the magnets 404 are disposed in either side of stator modules 402. For example, a first set of magnets 404 are disposed on a first side (e.g., a top side) of stator modules 402 and a second set of magnets 404 are disposed on a second side (e.g., a bottom side) of stator modules 402 opposite the first side. In some embodiments, the magnets 404 are coupled to the rotor 414. Interaction between the magnets 404 and the stator modules 402 (e.g., electro-magnetic interaction, etc.) may cause the rotor 414 to rotate. The rotor 414 may rotate about a central hub formed by the first housing 416 and the second housing 418. In some embodiments, a robot arm or linkage is coupled to the rotor 414.

In some embodiments, a lip seal 430 forms a seal within a space between the rotor 414 and the first housing 416 and/or the second housing 418. The lip seal 430 may be a rotary seal (e.g., for sealing a space between components that rotate relative to one another). The lip seal 430 may limit the amount of particles that can escape from within the space between the rotor 414, the first housing 416, and/or the second housing 418. In some embodiments, a first portion (e.g., an outer portion) of the lip seal 430 is coupled to the rotor 414 and a second portion (e.g., an inner portion) is coupled to one of the first housing 416 or the second housing 418. In some embodiments, an external vacuum pump (not illustrated) provides vacuum at conduit 428. The external vacuum pump may cause a vacuum condition within channel 422 and within first housing 416 and/or second housing 418. The space between first housing 416, second housing 418, and/or rotor 414 may be maintained at vacuum by the external vacuum pump. This space may be sealed from the vacuum environment outside the axial flux motor by lip seals 430. In some examples, while the vacuum environment external to the axial flux motor (e.g., in which the robot is to operate, substrates are transferred, etc.) may have a pressure of approximately 108 Torr, the external vacuum pump may maintain a vacuum environment having a pressure of approximately 103 Torr within the axial flux motor. The lip seals 430 may provide a seal between the two vacuum environments having different levels of vacuum. Therefore, the stator modules 402 (including the windings 403) and the magnets 404 may be within the vacuum environment internal to the motor.

FIG. 4B illustrates a side cutaway view 400B of a sealed axial flux motor for a vacuum robot, according to some embodiments. View 400B may show two such sealed axial flux motors, one stacked on top of the other. View 400B may show an arrangement of parts lacking the lip seals 430 shown in view 400A. In some embodiments, o-rings 426 form seals between the vacuum environment external to the motor and the vacuum environment internal to the motor. In some embodiments, o-rings 426 are disposed between the cap 420 and the first housing 416, between the first housing 416 and the second housing 418, and/or between the second housing 418 and the base 424. In such an arrangement, the stator modules 402 and the magnets 404 may be within the vacuum environment external to the motor (e.g., the vacuum environment where the robot is to operate, substrates are transferred, etc.).

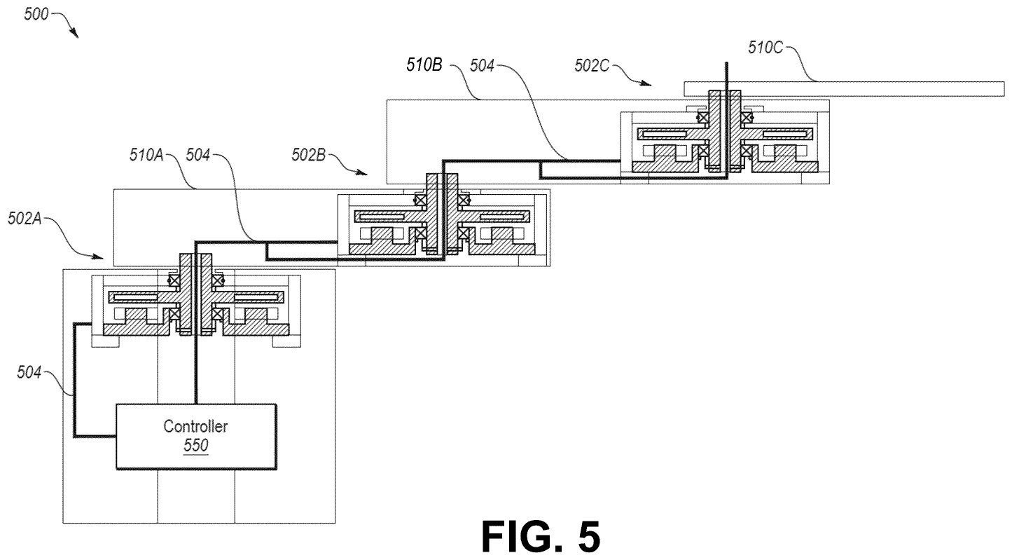

FIG. 5 illustrates a side cutaway view of a vacuum robot 500 having sealed axial flux motors 502, according to some embodiments. In some embodiments, robot 500 may include three sealed axial flux motors 502 to drive multiple robot arms 510. A first axial flux motor 502A may drive a first robot arm 510A, a second axial flux motor 502B may drive a second robot arm 510B, and a third axial flux motor 502C may drive a third robot arm 510C. The second motor 502B may be disposed within the first robot arm 510A at a distal end of the robot arm opposite the first motor 502A. The third motor 502C may be disposed within the second robot arm 510B at a distal end of the robot arm opposite the second motor 502B. In the example shown, robot arm 510C may include a substrate-handling end effector to transfer or transport a substrate responsive to the motion of the robot arms 510. Each of the axial flux motors 502 may be one of the axial flux motors shown in FIGS. 3A-4B, 7A, and 7B.

In some embodiments, a controller 550 provides control outputs for each of the axial flux motors 502. The control outputs may be carried by control wires 504 to each of the motors 502. In some embodiments, the control wires 504 pass through the center sections of the motors 502 to connect to the next motor 502. For example, control wires 504 for motors 502B and 502C may pass through a hollow center section of motor 502A and control wires for motor 502C may pass through a hollow center section of motor 502B. In some embodiments, the control wires 504 are joined by rotational connections to allow for complete and free rotation of the robot arms 510.

FIG. 6A illustrates a schematic diagram of a magnetic bearing 600 for use in a sealed axial flux motor, according to some embodiments. In some embodiments, the magnetic bearing 600 can be used in place of bearings 312, 412, or 712 in the arrangement of axial flux motors described herein. In some embodiments, magnetic bearing 600 includes an integral stator 602 and rotor 614. The stator 602 may include multiple windings wound around cores integral to the stator 602. The rotor 614 may include multiple magnets (e.g., permanent magnets) that are to interact with the stator 602 (e.g., to interact with the windings on stator 602). Electro-magnetic forces between the stator 602 and the rotor 614 may cause the rotor 614 to be centered within a center section formed in the stator 602, forming a gap 638 between the inner edge of the stator 602 and the outer edge of the rotor 614. By using electro-magnetic forces to form a gap 638 between the rotor 614 and the stator 602, the rotor 614 can rotate relative to the stator 602 without the use of conventional roller bearings, etc., reducing friction and wear on the parts.

FIG. 6B illustrates a schematic diagram of a stator 650 for an axial flux motor, according to some embodiments. In some embodiments, stator 650 includes a printed circuit board (PCB) having multiple stator modules 652 arranged radially around an open center section. Each of the stator modules 652 may be defined by windings 653 that are formed on the PCB. In some embodiments, the stator modules 652 may correspond to stator modules 302 and 402 described herein above. In some embodiments, the stator 650 can be used in an axial flux motor to simplify the manufacturing, to simplify the assembly, and/or to reduce the cost of an axial flux motor.

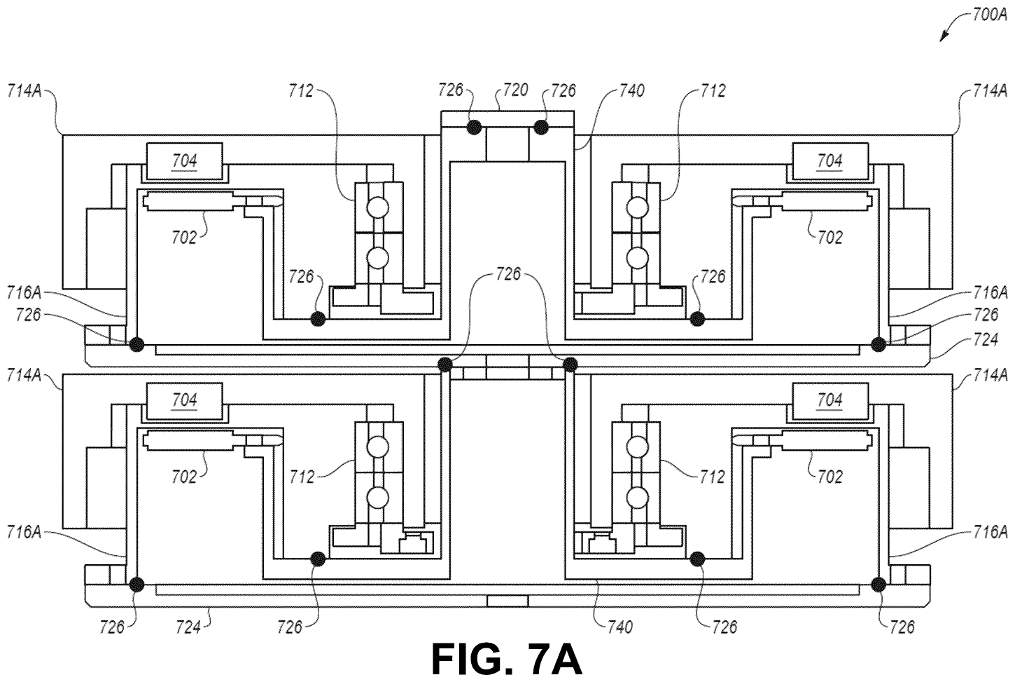

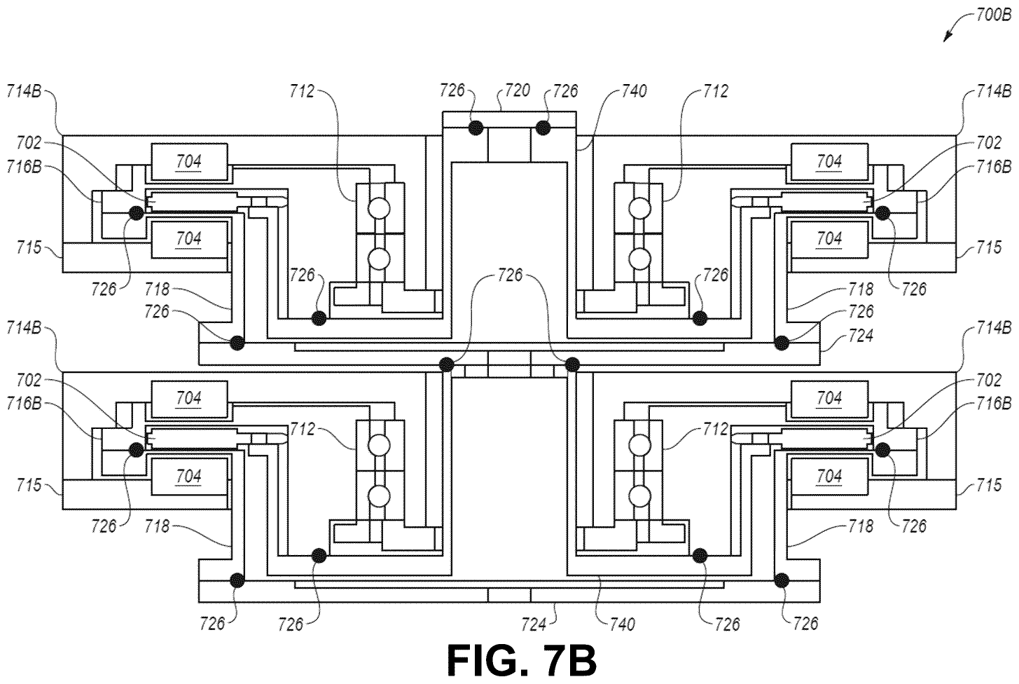

FIG. 7A illustrates a side cutaway view 700A of a sealed axial flux motor for a vacuum robot, according to some embodiments. View 700A may show two such sealed axial flux motors, one stacked on top of the other. In some embodiments, the axial flux motors shown in view 700A are single-sided-type axial flux motors. In some embodiments, features shown in view 700A having similar numbering to those shown in one of views 300A-300B and/or views 400A-400B may have similar features and/or functionality. For example, shown in view 700A are stator modules 702, magnets 704, bearings 712, rotor 714A, housing 716A, cap 720, base 724, and o-rings 726. In some embodiments, the housing 716A forms a vacuum barrier between the vacuum environment and the stator modules 702. At least one of the o-rings 726 may at least partially form a vacuum seal. In some embodiments, the housing 716A is coupled to the outer race of bearings 712 and the rotor 714A is coupled to the inner race of the bearings 712. The rotor 714A and the housing 716A may both be substantially circular in shape. In some embodiments, the rotor 714A at least partially surrounds the housing 716A.

In some embodiments, the stator modules 702 are supported by a stator support 740. In some embodiments, the stator support 740 is coupled to the housing 716A which is coupled to the base 724. In some embodiments, the stator support 740 is disposed substantially within an interior space formed by the housing 716A. The stator support 740 may include an open center channel for the passage of wires, coolant lines, etc. In some embodiments, the stator modules 702 are formed on a PCB (e.g., stator 650). For example, a PCB may form the stator modules 702 out of copper lines embedded and/or formed within the PCB. An outer portion of the stator support 740 may support the PCB. In some embodiments, the stator modules 702 are isolated from the vacuum environment at least partially by the housing 716A.

The magnets 704 may be attached to the rotor 714A on a first side (e.g., an underside, etc.) of the rotor 714A. In some embodiments, rotor 714A includes only one set of magnets which are disposed on one side of the stator modules 702. For example, the magnets 704 may be disposed on a first side (e.g., beneath) of the rotor 714A while also being disposed on a second side (e.g., above) the stator modules 702 on an opposite side of a portion of the housing 716A from the stator modules 702. In some embodiments, the stator modules 702 interact with the magnets 704 through a portion of the housing 716A. The interaction of the magnets 704 with the stator modules 702 may cause the rotor 714A to rotate relative to the housing 716A and/or the stator support 740. In some embodiments, the rotor 714A can be coupled to a robot linkage. Rotation of the rotor 714A may cause the linkage to move. In some embodiments, the magnets 704 are exposed to the vacuum environment.

FIG. 7B illustrates a side cutaway view 700B of a sealed axial flux motor for a vacuum robot, according to some embodiments. View 700B may show two such sealed axial flux motors, one stacked on top of the other. In some embodiments, the axial flux motors shown in view 700B are central stator-type axial flux motors. In some embodiments, features shown in view 700B having similar numbering to those shown in one of views 300A-300B, views 400A-400B, and/or views 700A-700B may have similar features and/or functionality.

In some embodiments, a first set of magnets 704 are coupled to an upper rotor 714B and a second set of magnets 704 are coupled to a lower rotor 715. The upper rotor 714B and the lower rotor 715 may be coupled together and form a single unit. The upper rotor 714B may be coupled to the inner race of the bearings 712. The stator modules 702 may be disposed substantially between the upper rotor 714B and the lower rotor 715. The stator modules 702 may be disposed substantially between the two sets of magnets 704. The first set of magnets 704 may be disposed on a first side of the stator modules 702 and the second set of magnets 704 may be disposed on a second side of the stator modules 702 opposite the first side. The stator modules 702 may be disposed within an interior space formed by an inner housing 716B and an outer housing 718. The inner housing 716B and the outer housing 718 may be coupled together and may form a vacuum barrier between the vacuum environment and the stator modules 702. The inner housing 716B may be coupled to the outer race of the bearings 712.

The preceding description sets forth numerous specific details such as examples of specific systems, components, methods, and so forth in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Relative position terms such as “top” and “bottom” as used herein are not to be construed as limiting and are merely used herein for convenience. Relative terms used herein such as “top” and “bottom” do not necessarily mean that the top component is above the bottom component. In some instances, the bottom component may be positioned over the top component.

Although the operations of the methods herein are shown and described in a particular order, the order of operations of each method may be altered so that certain operations may be performed in an inverse order so that certain operations may be performed, at least in part, concurrently with other operations. In another embodiment, instructions or sub-operations of distinct operations may be in an intermittent and/or alternating manner.

It is understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A robot, comprising:
a first robot linkage; and
a first axial flux motor configured to drive the first robot linkage, wherein the first axial flux motor comprises:
a housing;
a rotor coupled to the first robot linkage; and
multiple stator modules within the housing, wherein at least a portion of the housing is to form a sealing barrier between the multiple stator modules and a vacuum environment.

2. The robot of claim 1, wherein the housing forms multiple pockets, each of the multiple pockets to house one of the multiple stator modules, and wherein the multiple stator modules each comprise multiple conductive windings wound around a core.

3. The robot of claim 1, wherein the multiple stator modules are sealed from the vacuum environment at least in part by the sealing barrier and one or more seals.

4. The robot of claim 1, wherein the housing comprises an upper portion and a lower portion, and wherein a region between the upper portion and the lower portion is sealed by one or more seals.

5. The robot of claim 1, wherein the rotor comprises multiple magnets exposed to the vacuum environment, and wherein the rotor is configured to rotate based on an interaction between the multiple magnets and the multiple stator modules.

6. The robot of claim 1, further comprising:
a second robot linkage; and
a second axial flux motor configured to drive the second robot linkage.

7. The robot of claim 6, wherein the second axial flux motor is disposed adjacent to the first axial flux motor and shares a common axis with the first axial flux motor, or wherein the second axial flux motor is disposed at a distal end of the first robot linkage opposite the first axial flux motor.

8. The robot of claim 1, wherein a first set of the multiple stator modules are disposed on a first side of the rotor, and wherein a second set of the multiple stator modules are disposed on a second side of the rotor opposite the first side.

9. The robot of claim 1, wherein the multiple stator modules are disposed on a printed circuit board (PCB).

10. An axial flux motor, comprising:
a housing;
a rotor configured to couple to a robot linkage; and
multiple stator modules within the housing, wherein at least a portion of the housing is to form a sealing barrier between the multiple stator modules and a vacuum environment.

11. The axial flux motor of claim 10, wherein the housing forms multiple pockets, each of the multiple pockets to house one of the multiple stator modules, and wherein the multiple stator modules each comprise multiple conductive windings wound around a core.

12. The axial flux motor of claim 10, wherein the multiple stator modules are sealed from the vacuum environment at least in part by the sealing barrier and one or more seals.

13. The axial flux motor of claim 10, wherein the housing comprises an upper portion and a lower portion, and wherein a region between the upper portion and the lower portion is sealed by one or more seals.

14. The axial flux motor of claim 10, wherein the rotor comprises multiple magnets exposed to the vacuum environment, and wherein the rotor is configured to rotate based on an interaction between the multiple magnets and the multiple stator modules.

15. The axial flux motor of claim 10, wherein a first set of the multiple stator modules are disposed on a first side of the rotor, and wherein a second set of the multiple stator modules are disposed on a second side of the rotor opposite the first side.

16. The axial flux motor of claim 10, wherein the multiple stator modules are disposed on a printed circuit board (PCB).

17. An axial flux motor, comprising:
a housing;
a rotor configured to couple to a movable member;
a stator coupled to the housing; and
one or more rotary seals configured to seal the stator and an inner portion of the rotor from a first environment.

18. The axial flux motor of claim 17, wherein the rotor comprises multiple magnets, and wherein the housing forms a central hub about which the rotor is configured to rotate based on an interaction between the multiple magnets and the stator.

19. The axial flux motor of claim 18, wherein a first set of the multiple magnets are disposed on a first side of the stator, and wherein a second set of the multiple magnets are disposed on a second side of the stator opposite the first side.

20. The axial flux motor of claim 17, wherein the stator and the rotor are disposed within a second environment that is configured to be maintained at vacuum by an external vacuum pump, and wherein the one or more rotary seals are configured to isolate the second environment from the first environment.
